(19) United States
(12) Patent Application Publication
(10) Pub. No.: US 2021/0086286 A1
(43) Pub. Date: Mar. 25, 2021

(54) MAGNETIC CONFINEMENT HEATING DEVICE FOR SELECTIVE ADDITIVE MANUFACTURING APPARATUS

(71) Applicants: AddUp, Cebazat (FR); Centre National De La Recherche Scientifique (CNRS), Paris (FR); Universite Paris-Saclay, Saint Aubin (FR)

(72) Inventors: GILLES WALRAND, Cebazat (FR); TIBERIU MINEA, Paris (FR); CHARLES BALLAGE, Bures Sur Yvette (FR); DANIEL LUNDIN, Massy (FR); THOMAS PETTY, Bourg La Reine (FR)

(21) Appl. No.: 17/045,710

(22) PCT Filed: Apr. 5, 2019
(86) PCT No.: PCT/FR2019/050809

§ 371 Date: Oct. 6, 2020

(30) Foreign Application Priority Data
Apr. 6, 2018 (FR) 1853031

(51) Int. Cl. B23K 10/02; B33Y 10/00; B33Y 30/00; B33Y 50/02; B28B 1/00; H05H 1/10

(52) U.S. Cl. CPC B23K 10/027; B33Y 10/00; B33Y 30/00; B23K 2103/52; B28B 1/001; H05H 1/10; B33Y 50/02

(57) ABSTRACT

A device for heating a bed of powder in an additive manufacturing apparatus comprising: a plasma generation device (20), said device being adapted to be positioned and displaced above the bed of powder, at a distance from the bed of powder allowing for the generation of the plasma thereon, an electrical power supply unit (22) for said plasma generation device, and a control unit (9) for controlling the power supply and the displacement of the plasma generation device The plasma generation device (20) comprises a magnetic plasma containment assembly.

### GENERAL TECHNICAL FIELD AND PRIOR ART

The present invention relates to the general field of selective additive manufacturing.

More particularly, it relates to the heating treatments, and notably preheating, possibly in situ post-treatment by heating that is implemented on the beds of powder before the selective melting.

Selective additive manufacturing involves producing three-dimensional objects through consolidation of selected zones on successive strata of powdery material (metallic powder, ceramic powder, etc.). The consolidated zones correspond to successive sections of the three-dimensional object. The consolidation is done for example layer by layer, by total or partial selective melting produced with a power source (high-power laser beam, electron beam, etc.).

Conventionally, to avoid spatter due to the electrostatic repulsion of adjacent powder particles which are charged under the effect of the beam from the power source, the bed of powder is previously consolidated by a preheating. This preheating ensures a rise in the temperature of the bed of powder to temperatures which can be fairly high (approximately 750° C. for the titanium alloys).

It does however have a high energy cost.

It also represents a loss in terms of significant cycle time.

In order to optimize the efficiencies of the power sources used, it is known practice to work in a hermetic enclosure in which a partial vacuum is produced, notably in order to reduce the energy transfers between the signal emitted by the power source and the surrounding atmosphere so as to enhance the energy transfers between the power source and the bed of powder.

### General Description of the Invention

A general aim of the invention is to mitigate the drawbacks of the configurations proposed hitherto.

Notably, one aim of the invention is to propose a solution which allows for a heating without the powder being charged and lifted.

Another aim is to propose a heating solution (performed before or after a selective melting step) that operates at very low pressure, so as to optimize the efficiencies of the powder melting device.

Yet another aim is to propose a solution which makes it possible to reduce the preheating or post-treatment costs and times by heating within the manufacturing cycles.

Another aim of the invention is to propose a solution that is simple to construct.

Another aim is also to propose a heating solution that is effective, over a wide range of pressures, while remaining at low pressure (<0.1 mbar).

Thus, according to a first aspect, the invention proposes a device for heating a bed of powder in an additive manufacturing apparatus, characterized in that it comprises:
a plasma generation device, said device being adapted to be positioned and displaced above the bed of powder, at a distance from the bed of powder allowing for the generation of the plasma thereon,
an electrical power supply unit for said plasma generation device,
a control unit for controlling the power supply and the displacement of the plasma generation device,
   and in that the plasma generation device comprises a magnetic plasma containment assembly.

In this way, the plasma is contained and localized in a restricted zone, optimizing the preheating of the bed of powder.

The energy efficiency of the heating cycle is therefore enhanced, thereby reducing the duration and the cost of a preheating or heating cycle.

Such a device can advantageously be complemented by the following features, taken alone or in combination:
the plasma containment assembly comprises a device of magnetron type suitable for containing charged particles;
the magnetron device comprises an arrangement of magnets configured to contain electrons according to a linear pattern;
the device of magnetron type comprises a slit forming a source of ions, the slit being formed through the electrode and emerging facing the bed of powder;
a gas is injected into the slit;
the plasma generation device is adapted to be displaced with a main displacement component at right angles to the direction in which it extends;
the electrical power supply unit for said plasma generation device comprises a source of direct and/or radiofrequency and/or pulsed high voltage.

According to a second aspect, the invention proposes an apparatus for manufacturing a three-dimensional object by selective additive manufacturing comprising, in an enclosure:
a support for the deposition of the successive layers of additive manufacturing powder,
a dispensing arrangement suitable for applying a layer of powder on said support or on a previously consolidated layer,
at least one power source suitable for the selective consolidation of a layer of powder applied by the dispensing arrangement,

the apparatus comprising a heating device according to the present invention, the plasma generation device of the heating device being adapted to be positioned and displaced above the bed of powder, at a distance from the bed of powder allowing for the generation of the plasma thereon, the plasma generation device also comprising a magnetic plasma containment assembly.

This apparatus can comprise a dispensing arrangement comprising a layering scraper or roller, the plasma generation device extending in proximity to said scraper or roller and being mobile therewith, or placed on an independent mobile device such as a robot arm for example.

According to a third aspect, the invention proposes a manufacturing of a three-dimensional object by selective additive manufacturing, said method comprising the steps of:
deposition of a layer of powder on a support or a previously solidified layer,
consolidation of the previously preheated zone, the consolidation being performed by means of a power source,

the method also comprising a step of heating of at least one localized zone of the layer of powder by means of a heating device according to the present invention, the heating of the bed of powder being performed by a contained plasma.

Such a method can advantageously be complemented by the following features, taken alone or in combination:
during the heating step, the plasma generation device contains the charged particles in a precise location, so as to control the formation of the electrical discharges in the powering of the electrode, generating a contained plasma so as to maximize the heat transfer between the plasma and the bed of powder;
during the heating step, a gas is injected into the plasma generation device to be ionized therein, the magnetic field inducing a spraying of the ionized gas so as to generate a contained plasma jet, oriented towards the powder;
at least one heating step is performed before and/or after the consolidation step.

### PRESENTATION OF THE FIGURES

Other features and advantages of the invention will emerge more from the following description, which is purely illustrative and nonlimiting, and should be read in light of the attached figures in which:

FIG. 1 is a schematic representation of an additive manufacturing apparatus comprising a heating device according to a possible embodiment of the invention;

FIG. 2 is a theoretical diagram of a plasma generation device heating a bed of powder according to the invention;

FIG. 3 is a schematic view in cross section of a magnetron plasma generation device according to the invention;

FIG. 4 is a diagram of the structure of an arrangement of magnets of a magnetron device according to the invention;

FIG. 5 is a 3D theoretical diagram, seen from below, highlighting the operation of a magnetron cathode device according to the invention;

FIG. 6 is a schematic view in cross section representing an embodiment of a magnetron cathode device according to the invention equipped as a variant with a rotary (cathode) electrode;

FIG. 7 is a 3D representation, seen from below, of a second embodiment of a plasma generation device with magnetic containment generating an ion beam according to the invention (known also as inverted magnetron);

FIG. 8 is a schematic representation of a bed of powder heated by means of a heating device according to the invention.

### DESCRIPTION OF ONE OR MORE IMPLEMENTATIONS AND EMBODIMENTS

General

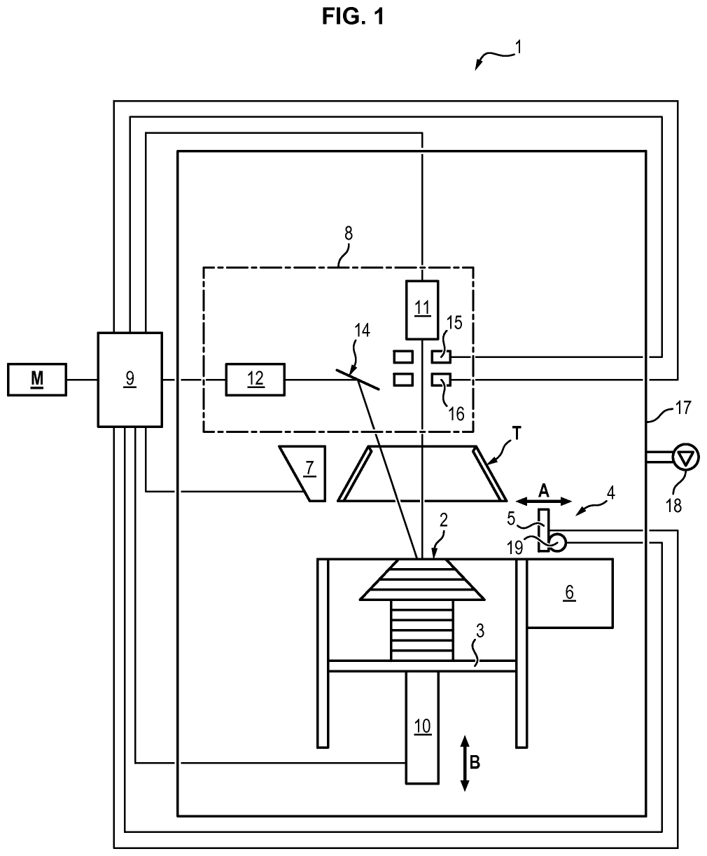

The selective additive manufacturing apparatus 1 of FIG. 1 comprises:
a support such as a horizontal plate 3 on which are successively deposited various layers of additive manufacturing powder (metallic powder, ceramic powder, etc.) that make it possible to manufacture a three-dimensional object (object 2 in the form of a fir tree in the figure),
a tank of powder 7 situated above the plate 3,
an arrangement 4 for dispensing said metallic powder on the plate, this arrangement 4 comprising, for example, a layering scraper 5 or roller for spreading the different successive layers of powder (displacement according to the double arrow A),
a set 8 of energy sources for the melting (total or partial) of the thin layers spread,
a control unit 9 which ensures the driving of the different components of the apparatus 1 according to prestored information (memory M),
a mechanism 10 for making it possible to lower the support of the deck 3 as the layers are deposited (displacement according to the double arrow B).

In the example described with reference to FIG. 1, the set 8 comprises two consolidation sources:
an electron beam gun 11 and
a source 12 of laser type.

As a variant, the set 8 can comprise only one source, for example a localized energy source in a vacuum or at very low pressure (<0.1 mbar): electron gun, laser source, etc.

Still as a variant, the set 8 can also comprise several sources of the same type, such as, for example, several electron guns and/or laser sources, or means that make it possible to obtain several beams from one and the same source.

In the example described with reference to FIG. 1, at least one galvanometric mirror 14 makes it possible to orient and displace the laser beam from the source 12 relative to the object 2 based on information sent by the control unit 9.

Any other deflection system can of course be envisaged.

In another example that is not illustrated, the set 8 comprises several sources 12 of laser type and the displacement of the different laser beams is obtained by displacing the different sources 12 of laser type above the layer of powder to be melted. Deflection and focusing coils 15 and 16 make it possible to deflect and locally focus the electron beam on the zones of layers to be sintered or melted.

A heat shield T can be interposed between the source or sources of the set 8.

The components of the apparatus 1 are arranged inside a sealed enclosure 17 linked to at least one vacuum pump 18 which maintains a secondary vacuum inside said enclosure 17 (typically approximately 10⁻²/10⁻³ mbar, even 10⁻⁴/10⁻⁶ mbar).

The apparatus also comprises a heating device 19 positioned above the bed of powder and that can be displaced linearly relative thereto.

This heating device 19 can be positioned behind the layering scraper 5 or roller on one and the same sliding carriage. It can also be mounted on an independent carriage or on a robot arm. In the latter case (not illustrated), the pattern described by the magnetic trap of the magnetron cathode can be of any form other than linear, for example allowing for a localized heating.

The displacement of said heating device 19, the powering thereof and its dwell time in front of the bed of powder that is to be heated or preheated are also controlled by the unit 9.

Heating by Magnetically Contained Linear Discharge

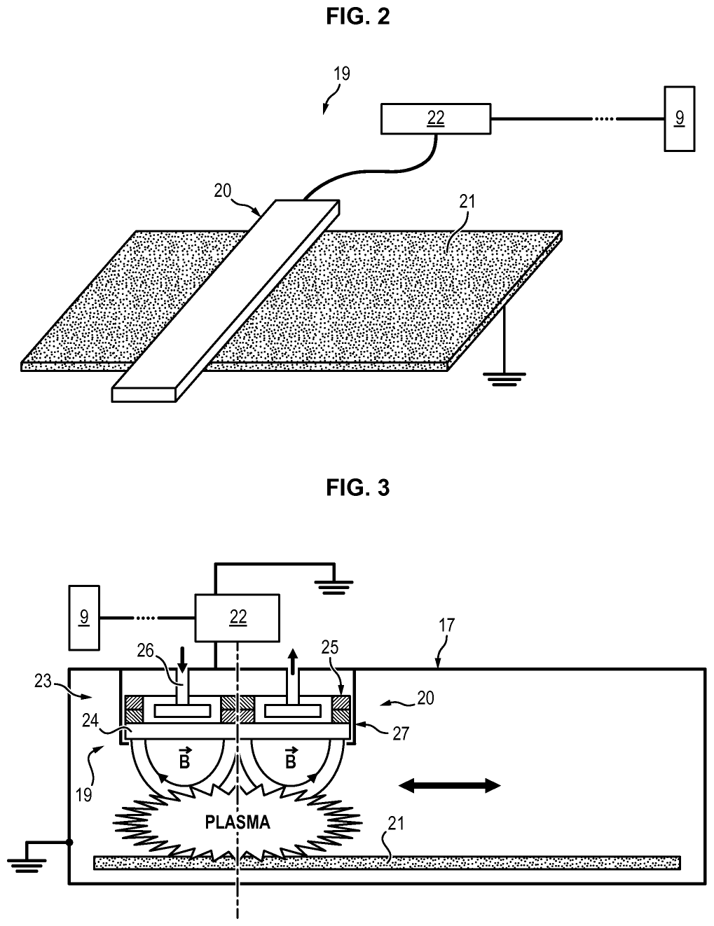

In the example illustrated in FIG. 2, the heating device 19 comprises a plasma generation device 20 that is displaced above the bed of metallic powder (solid or granular surface 21, composed of micro- or nano-powder).

This plasma generation device 20 is powered by an electrical excitation source 22 controlled by the control unit 9.

The source 22 allows for the application of a high voltage (>0.2 kV) between the plasma generation device 20 and the surface 21 of the bed of powder.

The power supply thus produced by the source 22 can be DC current, at low frequency, at radio frequency (RF), or pulsed.

The plasma generation device 20 generates, under the effect of said source 22, electrical discharges between the plasma generation device 20 and the surface 21 and creates a plasma, which ensures the heating of the surface 21.

The plasma generation device 20 extends substantially parallel to the surface 21. It is displaced parallel to said surface 21, at right angles to the direction in which it extends.

Such a configuration allows for a uniform heating on a surface of a bed of powder corresponding to the length of the plasma generation device 20 and the displacement distance thereof.

The surface 21 of the bed of powder is for example linked to the ground.

The heating can be performed before the consolidation step, therefore constituting a preheating step, so as to avoid powder spatter.

Optionally, a heating step can be performed after the consolidation step, therefore constituting a post-heating step, so as to perform a bake of the material or limit the quenching effect by the working atmosphere, or even control the trend of the temperature in cooling so as to obtain a particular crystalline structure.

Linear Magnetron Device

In order to generate a low-pressure plasma (<0.1 mbar) and so as to enhance the efficiencies of the plasma generation device 20, this device comprises a magnetic plasma containment system.

FIG. 3 shows a plasma containment assembly comprising a linear plasma generation magnetron device 23.

It comprises an electrode 24, preferably negatively polarized (by, in this case, acting as cathode).

An arrangement of magnets 25, positioned facing a first face of the electrode 24, generates a magnetic trap which allows the containment of the electrons facing the other face of the electrode 24.

The magnets can be permanent or electromagnets, or even a combination of the two.

Depending on the needs, the electrode 24 can be powered (source 22) with direct current (DC), at radio frequency (RF) or in high power pulsed mode (HiPIMS—High Power Impulse Magnetron Sputtering), but generally receiving a negative voltage.

Based on its power supply mode, the constituent material of the electrode 24 can be an electrical conductor, an insulator or a semiconductor.

In the case of an electrode 24 made of an electrically conductive material, all the electrical power supply modes are suitable.

In the case of an electrode 24 made of non-conductive material, only the RF or pulsed modes are suitable.

A circulation 26 of a coolant (for example water, glycol, etc.) is provided in the electrode 24, supplied by an external system.

The coolant can for example be injected through orifices formed in one of the walls of the carriage 27, and can for example be circulated between the rows of magnets of the arrangement of magnets 25, the fluid being thus also in contact with the electrode 24 and cooling the latter.

The coolant can then be extracted through a second orifice formed in the carriage 27.

Such a magnetron device 23 is mounted inside the enclosure 17 on a carriage 27 positioned above the bed of powder and that can be displaced linearly relative thereto (double arrow in the figure).

This carriage 27 is, for example, that of the layering roller, the magnetron device 23 being positioned behind said roller (relative to the direction of advance thereof).

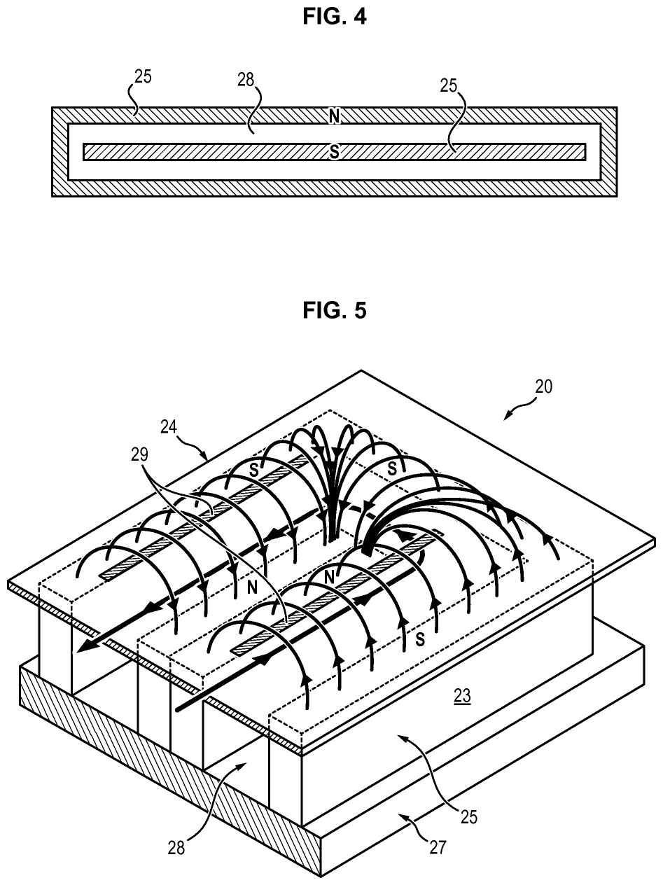

Referring to FIG. 4, an example of arrangement of magnets 25 comprises two rows of magnets positioned so as to form a linear track 28.

The magnets of reversed polarities are thus positioned on either side of the track 28.

In the example illustrated, the magnetic track 28 is closed.

Referring to FIG. 5, the arrangement of magnets 25 is covered by the electrode 24.

The magnetic field generated by the magnets traps the electrons around the magnetic field lines, on the side of the electrode 24 facing the bed of powder, and thus increases the ionization of the gas along a linear pattern 29 situated along the track 28, as illustrated in FIG. 5.

This magnetic configuration concentrates the electrons along the pattern 29, forming a plasma along said pattern 29.

In order to further increase the effectiveness of the trap, an alternating arrangement (north outside and south at the centre, or vice versa) is generally produced to produce a closed magnetic track 28 as illustrated in FIG. 4.

Operation of the Magnetron Discharge Device

The arrangement of magnets 25 is therefore configured to generate a magnetic field which concentrates the electrons in a determined zone. In the example described, it is a linear pattern 29, but the magnets could be arranged so as to form any other geometrical model, such as a circle or a curve.

When the electrode 24 is powered, an electrical discharge occurs between the bed of powder and the electrode 24, thus generating a plasma.

The concentration of the electrons in a determined zone makes it possible to promote the local ionization of the gas in the zone, and the presence of a magnetic trap makes it possible to contain the plasma in a precise zone, even at very low pressure.

Such a device is suited to low pressure operation, typically around 1 Pa (10⁻² mbar), but more widely over a range of pressures ranging from a microbar (0.1 Pa) to a millibar (100 Pa).

This order of pressure magnitude (in the region of a Pascal) makes it possible to enhance the efficiencies of the power sources producing the melting of the powders.

More specifically, in the particular case where the power source 12 comprises an electron beam generator, a low operating pressure implies a lower density of the surrounding atmosphere and therefore fewer impacts between the electrons emitted by the source 12 and the surrounding gas.

The presence of a magnetic field makes it possible to concentrate the electrons in a zone and therefore promote the formation of a plasma despite the low density of the surrounding atmosphere.

The width of the heated zone is then reduced, which enhances precision of the heating.

In the case where the power source 12 comprises a laser, the reduction of the operating pressure limits the surrounding oxygen level, which limits the formation of oxides and of fumes.

The molten material is therefore less polluted by the fumes and oxides.

The denudation effect, which consists in a depletion of the metallic powders in the zone surrounding the solidified track because of the blowing of these powders by a metallic vapour flux generated by the melting of the powders during the laser heating, is also greatly limited by reducing the surrounding pressure.

The metallic vapours produced in the melting of the powders are then less dense and flow circulating these vapours does not blow the powders.

The magnetic field B is configured to trap only the electrons, without affecting the behaviour of the ions.

In particular, the value of the magnetic field (typically a few 100 Gauss=0.01 Tesla) configured according to the mass difference between the electrons and the ions makes it possible to obtain this behaviour.

Indeed, the mass ratio between the electrons and the ions generates a similar ratio between their respective magnetic gyration radii (gyromagnetic radii).

The plasma thus created is contained between the electrode 24 and the free surface 21 of the bed of powder.

By placing such a magnetron device 23 with the homogeneous part (plasma or ion beam) towards the bed of powder, it is possible to effectively transfer energy from the species of the plasma to the powder and thus produce the heating thereof.

The energy is transmitted to the powder by multiple ways coexisting simultaneously in a plasma. These are charged species, electrons and ions, but also energy-neutral species, notably the neutral atoms sputtered from the electrode (cathode), the non-radiative excited states (metastable), and the photons. As the surface (powder) receives the two charged species, the charge effects (Coulombian repulsion) are reduced, even eliminated.

Furthermore, all the visible, infrared and ultraviolet photons heat the material when they are absorbed.

The denser the plasma, the greater the energy transmitted to the surface.

The quantity of energy, in the case of the ions but more generally for any type of plasma, can be easily adjusted by the ion acceleration voltage or, respectively, the power injected into the plasma. A better control can be produced by the pulsed operation of the plasma, alternating heating phases (plasma ON) and thermal expansion phases (plasma OFF). The alteration of the ON/OFF period, known also as the duty cycle, makes it possible to easily adjust the temperature.

Rotating Electrode Device

The formation of a plasma between the electrode and the bed of powder provokes, in the case of prolonged activation, a significant heating of the electrode.

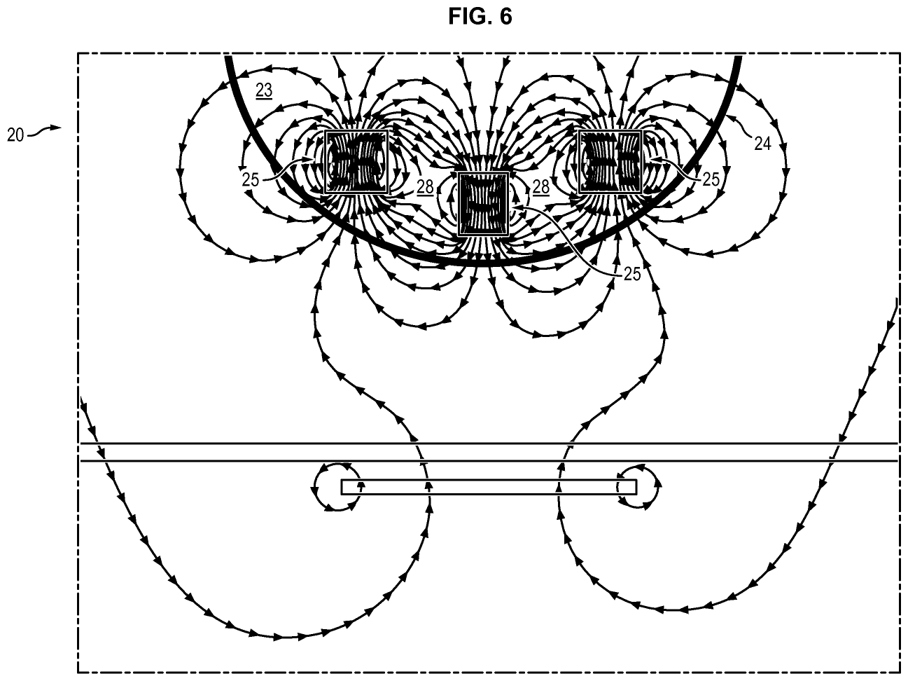

In some embodiments, the electrode 24 is a hollow cylindrical roller inside which the arrangement 25 of magnets is positioned, as illustrated in FIG. 6.

The arrangement of magnets 25 is fixedly mounted relative to the magnetron device 23, the electrode 24 being mounted to rotate along the axis along which it extends.

Thus, the position and the orientation of the magnetic field relative to the magnetron device 23 does not change during operation, making it possible to control the zone of formation of the plasma.

During the operation of the magnetron device 23, the electrode 24 is driven in rotation. In this way, the part of the electrode 24 which is exposed to the plasma changes regularly, limiting the heating of a particular zone, the plasma being always contained in the magnetic trap generated by the arrangement of magnets 25 which has a fixed orientation relative to the magnetron device 23, notably towards the surface 21 of the bed of powder, as illustrated in FIG. 6.

Linear Ion Source Device

Variant magnetron cathodes also make it possible to obtain a linear and homogeneous plasma.

In the case of the embodiment of FIG. 3, the electrode 24 is a planar electrode.

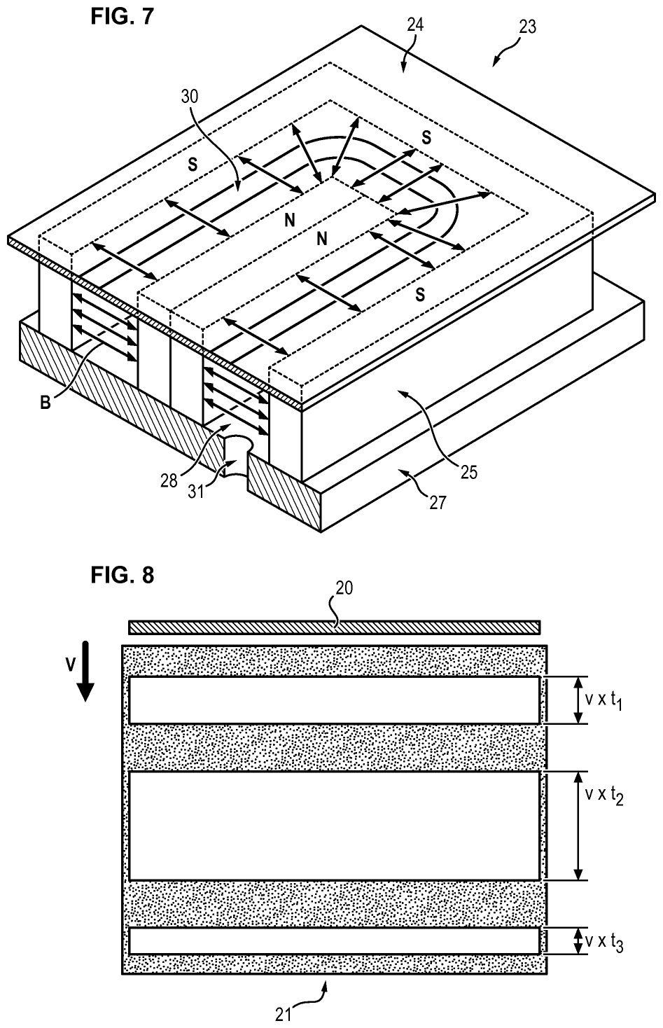

In a variant illustrated in FIG. 7, the magnetron device can comprise an electrode 24 in which a slit 30 is formed.

The slit 30 is formed facing the track 28, the track 28 being formed by a cavity extending between the rows of the arrangement of magnets 25.

An injection orifice 31 is formed in a wall of the carriage 27, at the bottom of the cavity formed by the track 28 and the slit 30.

A gas is injected into the cavity through the injection orifice 31. Upon the excitation of the cathode 24, the gas is then strongly ionized by the electrons effectively trapped by the magnetic field B generated by the arrangement of magnets 25.

Optionally, the gas injected through the injection orifice 31 is the gas forming the working atmosphere, making it possible to simplify the apparatus.

The cavity formed by the track 28 and the slit 30 therefore forms a source of ions.

The magnetic barrier generated by the arrangement of magnets 25 increases the electrical resistance of the plasma, thus generating a potential difference in the plasma by Hall effect.

A movement of charges generated by the magnetic field B and an electrical field generated by the excitation of the cathode 24 provokes a circulation of the electrons along the track 28, facing the slit 30, leading to the homogenization of the plasma.

The ions, not magnetized, are sprayed by the electrical field through the slit 30.

Some electrons, more lightweight, follow the ions. Thus, a contained plasma flux is generated and sprayed through the slit 30. The slit 30 is ideally situated facing the bed of powder, so as to spray the plasma jet onto the surface 21 to be heated.

In a variant, the plasma generation device 20 is of any form other than linear and it is adapted to be displaced with a robot.

By placing the plasma generation device 20 in front of the surface 21 of powder, it is possible to maintain a high-density plasma, that is homogeneous and contained between said device 20 and the bed of powder, despite the low working pressure.

By displacing this plasma generation device 20, it is possible to scan the surface 21 of the bed of powder. By keeping the plasma on and by performing a complete scan of the surface 21 of the bed of powder, the bed of powder is superficially heated.

Optionally, depending on the plasma on time (time t₁, t₂ or t₃) and on the position of the plasma generation device 20 above the bed of powder, only certain zones can be heated, over all the width of the bed of powder, as illustrated in FIG. 8.

By limiting the plasma on time, it is possible to optimize the energy consumption while producing the desired heating.

Energy is thus transferred efficiently to the powder, which makes it possible to produce the heating thereof.

1.-13. (canceled)

14. A heating device for heating a bed of powder in an additive manufacturing apparatus, the heating device comprising:
a plasma generation device,
the heating device being configured for heating a bed of powder in an additive manufacturing apparatus,
the plasma generation device being configured for being positioned and displaced above the bed of powder, at a distance from the bed of powder allowing for generation of a plasma thereon, and
the plasma generation device comprising a magnetic plasma containment assembly;
an electrical power supply unit for the plasma generation device; and
a control unit for controlling the power supply and a displacement of the plasma generation device.

15. The heating device according to claim 14, wherein the magnetic plasma containment assembly comprises a device of magnetron type suitable for containing charged particles.

16. The heating device according to claim 15, wherein the device of magnetron type comprises an arrangement of magnets configured to contain electrons according to a linear pattern.

17. The heating device according to claim 16, wherein the device of magnetron type comprises a slit forming a source of ions, the slit being formed through an electrode and emerging facing the bed of powder.

18. The heating device according to claim 17, further comprising injection means configured for injecting a gas into the slit.

19. The heating device according to claim 14, wherein the plasma generation device is configured for being displaced with a main displacement component at right angles to a direction in which the plasma generation device extends.

20. The heating device according to claim 14, wherein the electrical power supply unit for the plasma generation device comprises a source of high direct and/or radiofrequency and/or pulsed voltage.

21. An apparatus for manufacturing a three-dimensional object, the apparatus comprising means for manufacturing a three-dimensional object by selective additive manufacturing, and the apparatus comprising, in an enclosure:
a support;
a dispensing arrangement configured for applying a layer of additive manufacturing powder on the support or on a previously consolidated layer of additive manufacturing powder; and
at least one power source configured for making a selective consolidation of the layer of additive manufacturing powder applied by the dispensing arrangement,
the apparatus comprising a heating device according to claim 14,
the plasma generation device of the heating device being configured to be positioned and displaced above the layer of additive manufacturing powder, at a distance from the layer of additive manufacturing powder allowing for a generation of a plasma thereon, and
the plasma generation device comprising a magnetic plasma containment assembly.

22. The apparatus according to claim 21, wherein the dispensing arrangement comprises a layering scraper or roller, the plasma generation device extending in proximity to a scraper or roller and being mobile therewith or being displaced independently.

23. A method for manufacturing a three-dimensional object, the method comprising manufacturing a three-dimensional object by selective additive manufacturing, and the method comprising the steps of:
depositing a layer of powder on a support or a previously solidified layer;
consolidating at least one zone of the layer of powder by means of a power source;
heating at least one localized zone of the layer of powder, the heating comprising generating a contained plasma on the layer of powder using a plasma generation device comprising a magnetic plasma containment assembly; and
positioning and displacing the plasma generation device above the layer of powder, at a distance from the layer of powder.

24. The method according to claim 23, wherein, during the heating step, the plasma generation device:
contains charged particles within a precise location so as to control a formation of electrical discharges in a powering of the electrode; and
generates a plasma that is contained so as to maximize a heat transfer between the plasma and the layer of powder.

25. The method according to claim 23, wherein, during the heating step, a gas is injected into the plasma generation device to be ionized therein, and
a magnetic field induces a spray of the ionized gas so as to generate a contained plasma jet oriented toward the powder.

26. The method according to claim 23, wherein at least a supplementary heating step is performed before and/or after the consolidating step.
